(19) United States
(12) Patent Application Publication
(10) Pub. No.: US 2009/0152740 A1
(43) Pub. Date: Jun. 18, 2009

(54) INTEGRATED CIRCUIT PACKAGE SYSTEM WITH FLIP CHIP

(76) Inventors: Soo-San Park, Seoul (KR); BumJoon Hong, Seoul (KR); Sang-Ho Lee, Yeoju (KR); Jong-Woo Ha, Seoul (KR); DaeSik Choi, Seoul (KR)

Correspondence Address: LAW OFFICES OF MIKIO ISHIMARU, 333 W. EL CAMINO REAL, SUITE 330, SUNNYVALE, CA, 94087, US

(21) Appl. No.: 11/957,862

(22) Filed: Dec. 17, 2007

(51) Int. Cl. H01L 23/538

(52) U.S. Cl. 257/778; 257/E23.178

(57) ABSTRACT

An integrated circuit package system includes: mounting a flip chip over a carrier with a non-active side of the flip chip facing the carrier; mounting a substrate over the flip chip; connecting an internal interconnect between the flip chip and the carrier; and encapsulating the flip chip and the internal interconnect over the carrier with the substrate exposed.

### TECHNICAL FIELD

The present invention relates generally to an integrated circuit package system and more particularly to an integrated circuit package system with flip chip.

### BACKGROUND ART

Increased miniaturization of components, greater packaging density of integrated circuits (“ICs”), higher performance, and lower cost are ongoing goals of the computer industry. Semiconductor package structures continue to advance toward miniaturization, to increase the density of the components that are packaged therein while decreasing the sizes of the products that are made therefrom. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

Many conventional semiconductor (or “chip”) packages are of the type where a semiconductor die is molded into a package with a resin, such as an epoxy molding compound. The packages have a lead frame whose leads are projected from the package body, to provide a path for signal transfer between the die and external devices. Other conventional package configurations have contact terminals or pads formed directly on the surface of the package. Such a conventional semiconductor package is fabricated through the following processes: a die-bonding process (mounting the semiconductor die onto the paddle of a lead frame), a wire-bonding process (electrically connecting the semiconductor die on the paddle to inner leads using lead frame wires), a molding process (encapsulating a predetermined portion of the assembly, containing the die, inner leads and lead frame wires, with an epoxy resin to form a package body), and a trimming process (completing each assembly as individual, independent packages).

The semiconductor packages, thus manufactured, are then mounted by matching and soldering the external leads or contact pads thereof to a matching pattern on a circuit board, to thereby enable power and signal input/output (“I/O”) operations between the semiconductor devices in the packages and the circuit board.

In response to the demands for improved packaging, many innovative package designs have been conceived and brought to market. The multi-chip module has achieved a prominent role in reducing the board space used by modern electronics. However, multi-chip modules, whether vertically or horizontally arranged, can also present problems because they usually must be assembled before the component chips and chip connections can be tested. That is, because the electrical bond pads on a die are so small, it is difficult to test die before assembly onto a substrate. Thus, when die are mounted and connected individually, the die and connections can be tested individually, and only known-good-die (“KGD”) that is free of defects is then assembled into larger circuits. A fabrication process that uses KGD is therefore more reliable and less prone to assembly defects introduced due to bad die. With conventional multi-chip modules, however, the die cannot be individually identified as KGD before final assembly, leading to KGD inefficiencies and assembly process yield problems.

Numerous package approaches stack multiple integrated circuit dice or package in package (PIP) or a combination. Other approaches include package level stacking or package on package (POP). Both concepts include stacking of two or more packages. KGD and assembly process yields are not an issue since each package can be tested prior to assembly, allowing KGD to be used in assembling the stack. Among all the approaches, flip chip has been an important subject for industry because it usually requires small space and small number of processing steps. However all the current package approaches still do not provide the flexibility to support the various integration and stacking options described earlier with one or more flip chips involved.

Thus, a need still remains for an integrated circuit package system providing low cost manufacturing, improved yields, reduction of integrated circuit package dimensions, and flexible stacking and integration configurations. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

An integrated circuit package system includes: mounting a flip chip over a carrier with a non-active side of the flip chip facing the carrier; mounting a substrate over the flip chip; connecting an internal interconnect between the flip chip and the carrier; and encapsulating the flip chip and the internal interconnect over the carrier with the substrate exposed.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a top view of an integrated circuit package system in a first embodiment of the present invention;

FIG. 2 is a cross-sectional view of an integrated circuit package system along line 2-2 of FIG. 1;

FIG. 3 is a cross-sectional view of an integrated circuit package system along line 2-2 of FIG. 1 in a second embodiment of the present invention;

FIG. 4 is a cross-sectional view of an integrated circuit package system along line 2-2 of FIG. 1 in a third embodiment of the present invention;

FIG. 5 is a cross-sectional view of an integrated circuit package system along line 2-2 of FIG. 1 in a fourth embodiment of the present invention;

FIG. 6 is a top view of an integrated circuit package system in a fifth embodiment of the present invention;

FIG. 7 is a cross-sectional view of an integrated circuit package system along line 7-7 of FIG. 6;

FIG. 8 is a cross-sectional view of the integrated circuit package system of FIG. 2 in a step for forming the flip chip;

FIG. 9 is the structure of FIG. 8 in a step for mounting the substrate;

FIG. 10 is the structure of FIG. 9 in a step for forming the underfill;

FIG. 11 is the structure of FIG. 10 in a step for forming the adhesive;

FIG. 12 is the structure of FIG. 11 in a step for attaching the carrier; and

FIG. 13 is a flow chart of an integrated circuit package system for manufacturing of the integrated circuit package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Generally, the invention can be operated in any orientation.

In addition, where multiple embodiments are disclosed and described having some features in common, for clarity and ease of illustration, description, and comprehension thereof, similar and like features from one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used.

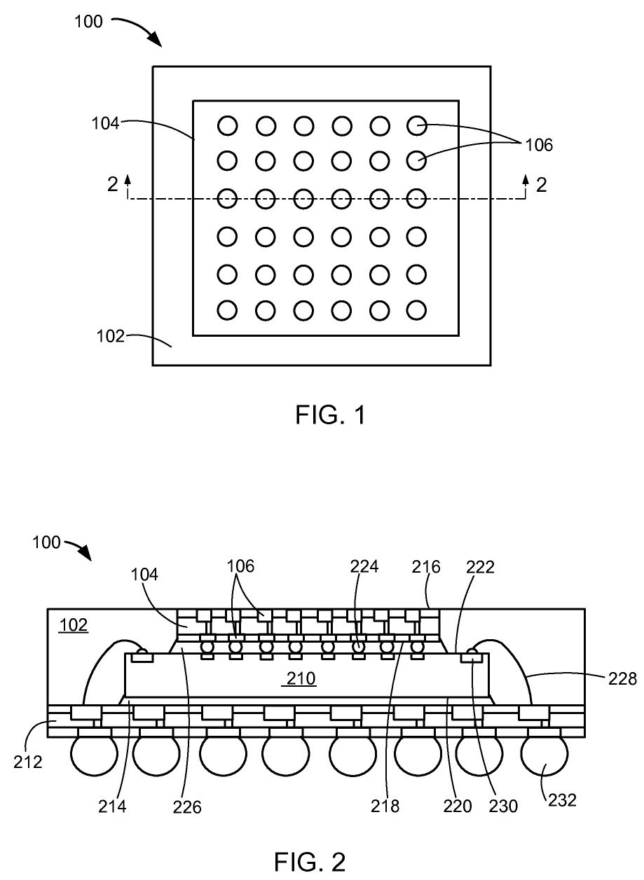

Referring now to FIG. 1, therein is shown a top view of an integrated circuit package system 100 in a first embodiment of the present invention. The top view depicts a package encapsulation 102, such as an epoxy molding compound, and a substrate 104, such as a laminated substrate, with contact pads 106 exposed from the package encapsulation 102.

For illustrative purposes, the integrated circuit package system 100 is shown with the contact pads 106 equally spaced. Although, it is understood that the integrated circuit package system 100 may have some sites depopulated such that the integrated circuit package system 100 may have the contact pads 106 not equally spaced.

Referring now to FIG. 2, therein is shown a cross-sectional view of the integrated circuit package system 100 along line 2-2 of FIG. 1. The cross-sectional view depicts a flip chip 210 mounted over a carrier 212, such as a laminated substrate, with an adhesive 214, such as a die-attach adhesive and the substrate 104 mounted over the flip chip 210. The package encapsulation 102 covers the flip chip 210 over the carrier 212 with the substrate 104 exposed.

The substrate 104 includes the contact pads 106 at both a top side 216 of the substrate 104 and a bottom side 218 of the substrate 104. The contact pads 106 at the top side 216 of the substrate 104 are exposed from the package encapsulation 102. The package encapsulation 102 is coplanar with the top side 216 of the substrate 104. The flip chip 210 has a non-active side 220 and an active side 222, wherein the active side 222 includes active circuitry fabricated thereon. In this example, the non-active side 220 preferably faces the carrier 212. First conductive bumps 224 connect the contact pads 106 at the bottom side 218 of the substrate 104 and the active side 222 of the flip chip 210. An underfill 226, such as an adhesive, may be between the substrate 104 and the active side 222 surrounding the first conductive bumps 224.

Internal interconnects 228, such as bond wires or ribbon bond wires, may connect between bond pads 230 on the active side 222 of the flip chip 210 and the carrier 212. The package encapsulation 102 also covers the internal interconnects 228. External interconnects 232, such as solder balls, may attach below and to the carrier 212 for connection to the next system level (not shown), such as a printed circuit board or another integrated circuit package system.

It has been discovered that the present invention provides dual connectivity with the substrate exposed from the package encapsulation and connected with the flip chip within the package encapsulation. The flip chip connects to the substrate with the conductive bumps and connects with the carrier with the internal interconnects while providing low cost and reliable method for other integrated circuit device and electric elements to be mounted over the substrate.

It has also been discovered that in the present invention that the substrate and the flip chip can be assembled and tested as a package before the subsequent manufacturing process of the integrated circuit package system. This feature can further reduce manufacturing cost and increase reliability.

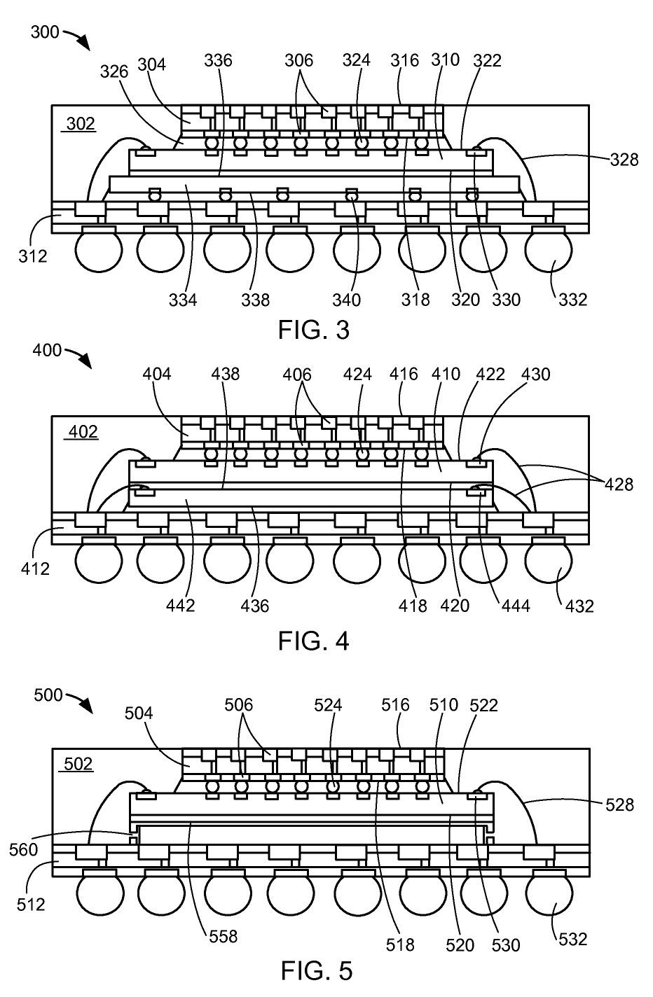

Referring now to FIG. 3, therein is shown a cross-sectional view of an integrated circuit package system 300 along line 2-2 of FIG. 1 in a second embodiment of the present invention. The top view of the integrated circuit package system 100 of FIG. 1 may also represent the top view of the integrated circuit package system 300. The cross-sectional view depicts a first flip chip 310 mounted over a carrier 312, such as a laminated substrate, and a substrate 304, such as a laminated substrate, mounted over the first flip chip 310. A package encapsulation 302, such as an epoxy molding compound, covers the first flip chip 310 over the carrier 312 and exposes the substrate 304.

The substrate 304 includes contact pads 306 at both a top side 316 of the substrate 304 and a bottom side 318 of the substrate 304. The contact pads 306 at the top side 316 of the substrate 304 are exposed from the package encapsulation 302. The package encapsulation 302 is coplanar with the top side 316 of the substrate 304. The first flip chip 310 has a first non-active side 320 and a first active side 322, wherein the first active side 322 includes active circuitry fabricated thereon. In this example, the first non-active side 320 preferably faces the carrier 312. First conductive bumps 324 may connect the contact pads 306 at the bottom side 318 of the substrate 304 and the first active side 322 of the first flip chip 310. An underfill 326, such as an adhesive, may be between the substrate 304 and the first active side 322 surrounding the first conductive bumps 324.

Between the first flip chip 310 and the carrier 312, a second flip chip 334 is mounted over the carrier 312. The second flip chip 334 has a second non-active side 336 and a second active side 338, wherein the second active side 338 includes active circuitry fabricated thereon. In this example, the second active side 338 preferably faces the carrier 312. Second conductive bumps 340 may connect the carrier 312 and the second active side 338 of the second flip chip 334.

Internal interconnects 328, such as bond wires or ribbon bond wires, connect between bond pads 330 at the first active side 322 of the first flip chip 310 and the carrier 312. External interconnects 332, such as solder balls, may attach to and below the carrier 312 for connection to the next system level (not shown), such as a printed circuit board or another integrated circuit package system.

Referring now to FIG. 4, therein is shown a cross-sectional view of an integrated circuit package system 400 along line 2-2 of FIG. 1 in a third embodiment of the present invention. The top view of the integrated circuit package system 100 of FIG. 1 may also represent the top view of the integrated circuit package system 400. The cross-sectional view depicts a flip chip 410 mounted over a carrier 412, such as a laminated substrate, and a substrate 404, such as laminated substrate, mounted over the flip chip 410. A package encapsulation 402, such as an epoxy molding compound, covers the flip chip 410 over the carrier 412 and exposes the substrate 404.

The substrate 404 includes contact pads 406 at both a top side 416 of the substrate 404 and a bottom side 418 of the substrate 404. The contact pads 406 at the top side 416 of the substrate 404 are exposed from the package encapsulation 402. The package encapsulation 402 is coplanar with the top side 416 of the substrate 404. The flip chip 410 includes a first non-active side 420 and a first active side 422, wherein the first active side 422 includes active circuitry fabricated thereon. In this example, the first non-active side 420 preferably faces the carrier 412. First conductive bumps 424 connect the contact pads 406 at the bottom side 418 of the substrate 404 and the first active side 422 of the flip chip 410.

Between the flip chip 410 and the carrier 412, an integrated circuit device 442, such as an integrated circuit die, may be mounted over the carrier 412. The integrated circuit device 442 includes a second non-active side 436 and a second active side 438, wherein the second active side 438 includes active circuitry and bonding pad 444 fabricated thereon. In this example, the second non-active side 436 preferably faces the carrier 412.

Internal interconnects 428, such as bond wire or ribbon bond wire, connect the carrier 412 and the bonding pad 444 of the integrated circuit device 442. The internal interconnects 428 also connect between bond pads 430 at the first active side 422 of the flip chip 410 and the carrier 412. External interconnects 432, such as solder balls, attach to and below the carrier 412 for connection to the next system level (not shown), such as a printed circuit board or another integrated circuit package system.

Referring now to FIG. 5, therein is shown a cross-sectional view of an integrated circuit package system 500 along line 2-2 of FIG. 1 in a fourth embodiment of the present invention. The top view of the integrated circuit package system 100 of FIG. 1 may also represent the top view of the integrated circuit package system 500. The cross-sectional view depicts a flip chip 510, mounted over a carrier 512, such as a laminated substrate, and a substrate 504, such as a laminated substrate, mounted over the flip chip 510. A package encapsulation 502, such as an epoxy molding compound, covers the flip chip 510 over the carrier 512 and exposes the substrate 504.

The substrate 504 includes contact pads 506 at both a top side 516 of the substrate 504 and a bottom side 518 of the substrate 504. The contact pad 506 at the top side 516 of the substrate 504 is exposed from the package encapsulation 502. The package encapsulation 502 is coplanar with the top side 516 of the substrate 504. The flip chip 510 has a non-active side 520 and an active side 522, wherein the active side 522 includes active circuitry fabricated thereon. In this example, the non-active side 520 preferably faces the carrier 512. First conductive bumps 524 connect the contact pads 506 at the bottom side 518 of the substrate 504 and the active side 522 of the flip chip 510.

Between the flip chip 510 and the carrier 512, a conductive shield 558, such as an electromagnetic interference (EMI) shield, may be mounted over the carrier 512. The conductive shield 558 may connect to a ground source through the carrier 512. The conductive shield 558 may provide EMI shielding between the flip chip 510 and circuit elements (not shown) that may be mounted within the conductive shield 558 and over the carrier 512. The conductive shield 558 includes apertures 560 for the package encapsulation 502 to flow into the conductive shield 558 such that the conductive shield 558 may also function as a mold lock.

Internal interconnects 528, such as bond wires or ribbon bond wires, connect between bond pads 530 at the active side 522 of the flip chip 510 and the carrier 512. External interconnects 532, such as solder balls, attach to and below the carrier 512 for connection to the next system level (not shown), such as a printed circuit board or another integrated circuit package system.

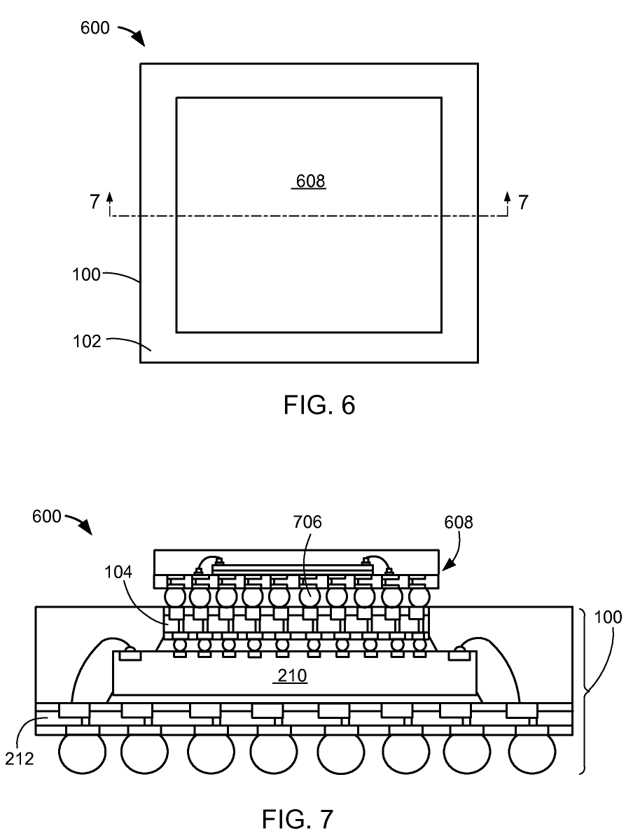

Referring now to FIG. 6, therein is shown a top view of an integrated circuit package system 600 in a fifth embodiment of the present invention. The integrated circuit package system 600 is an integrated circuit package-on-package system in an application with the integrated circuit package system 100. The top view depicts the package encapsulation 102 of the integrated circuit package system 100 with a device 608, such as a packaged integrated circuit, mounted thereon.

Referring now to FIG. 7, therein is shown a cross-sectional view of the integrated circuit package system 600 along line 7-7 of FIG. 1. The cross-sectional view depicts the device 608 mounted over the substrate 104 of the integrated circuit package system 100. For example, solder balls 706 may connect the device 608 and the substrate 104. The substrate 104 with the dual connectivity may function as a redistribution function between the device 608 and the flip chip 210, the carrier 212, and to the next system level (not shown).

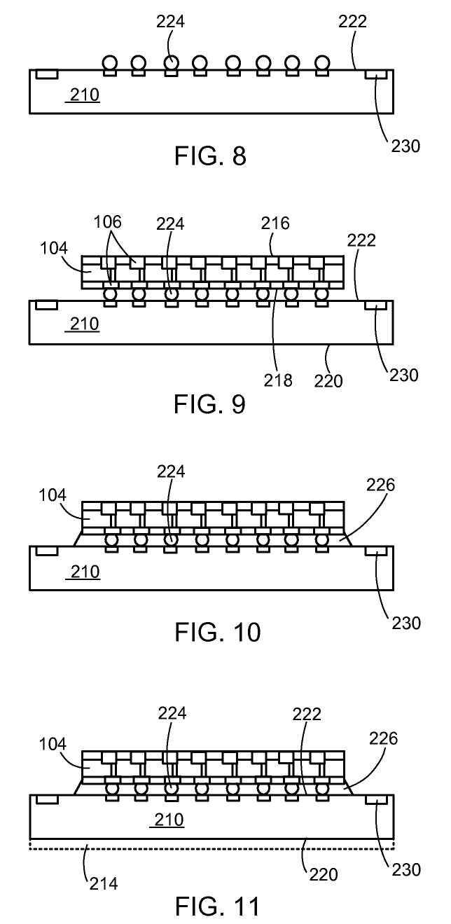

Referring now to FIG. 8, therein is shown a cross-sectional view of the integrated circuit package system 100 of FIG. 2 in a step for forming the flip chip 210. The cross-sectional view depicts the flip chip 210 with the first conductive bumps 224 and the bond pads 230 formed on the active side 222. The first conductive bumps 224 may be formed by a number of processes, such as solder bumping. The bond pads 230 at the periphery of the active side 222 are not bumped. For illustrative purpose, the flip chip 210 is shown as an individual device, although it is understood that the process may be done at wafer level, which includes a number of flip chips.

Referring now to FIG. 9, therein is shown the structure of FIG. 8 in a step for mounting the substrate 104. The cross-sectional view depicts the substrate 104 and the flip chip 210 with the first conductive bumps 224 and the bond pads 230. The flip chip has the non-active side 220 and the active side 222. The first conductive bumps 224 and the bond pads 230 are on the active side 222 of the flip chip 210. The substrate 104 is mounted over the active side 222 of the flip chip 210.

The substrate 104 has the contact pads 106 at both the top side 216 of the substrate 104 and the bottom side 218 of the substrate 104. The contact pads 106 at the bottom side 218 of the substrate 104 are aligned with the first conductive bumps 224. A reflow process may form electrical connections between the substrate 104 and the flip chip 210.

Referring now to FIG. 10, therein is shown the structure of FIG. 9 in a step for forming the underfill. The cross-sectional view depicts the substrate 104 and the flip chip 210 with the first conductive bumps 224 and the bond pads 230. As an intermediate step of manufacturing of the integrated circuit package system of the present invention, the underfill 226 is applied and cured to between the substrate 104 and the flip chip 210 surrounding the first conductive bumps 224. The underfill 226 may provide mechanical support between the substrate 104 and the flip chip 210.

Referring now to FIG. 11, therein is shown the structure of FIG. 10 in a step for forming the adhesive. The cross-sectional view depicts the substrate 104 mounted over the flip chip 210 with the first conductive bumps 224 connecting the substrate 104 with the flip chip 210. The flip chip 210 also includes the bond pads 230. The underfill 226 is between the substrate 104 and the flip chip 210. The flip chip 210 has the non-active side 220 and the active side 222.

The adhesive 214, such as epoxy or multi layered adhesive, may be applied to the non-active side 220 of the flip chip 210. As shown by dotted lines, the adhesive 214 may be a wafer backside laminated film such that this step may be optional.

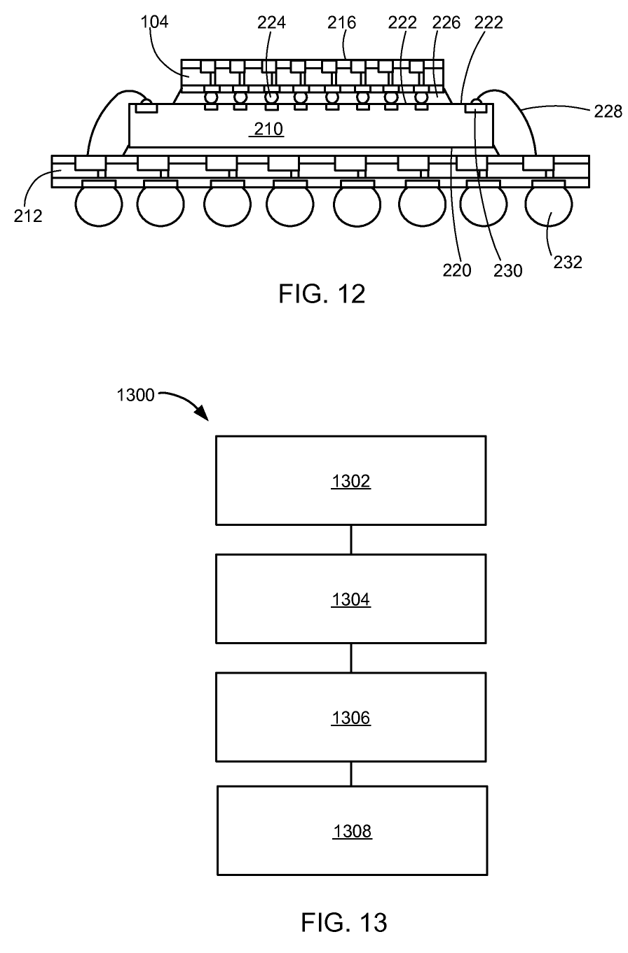

Referring now to FIG. 12, therein is shown the structure of FIG. 11 in a step for attaching the carrier. The cross-sectional view depicts the substrate 104, the carrier 212 and the flip chip 210 with the first conductive bumps 224 and the bond pads 230. The flip chip 210 includes the non-active side 220 and the active side 222. The internal interconnects 228 connect the bond pads 230 on the active side 222 of the flip chip 210 and the carrier 212. The external interconnects 232 attach below and to the carrier 212 for connection to the next system level (not shown). The package encapsulation 102 of FIG. 2 may be formed over the flip chip 210, the internal interconnects 228, and the carrier 212 with the top side 216 of the substrate 104 exposed forming the integrated circuit package system 100 of FIG. 2.

Referring now to FIG. 13, therein is shown a flow chart of an integrated circuit package system 1300 for manufacturing of the integrated circuit package system 100 in an embodiment of the present invention. The system 1300 includes mounting a flip chip over a carrier with an non-active side of the flip chip facing the carrier in a block 1302; mounting a substrate over the flip chip in a block 1304; connecting an internal interconnect between the flip chip and the carrier in a block 1306; and encapsulating the flip chip and the internal interconnect over the carrier with the substrate exposed in a block 1308.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit package system of the present invention furnishes important and heretofore unknown and unavailable solutions, capabilities, and functional aspects for improving yield, increasing reliability, and reducing cost of circuit system. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
mounting a flip chip over a carrier with a non-active side of the flip chip facing the carrier;
mounting a substrate over the flip chip;
connecting an internal interconnect between the flip chip and the carrier; and
encapsulating the flip chip and the internal interconnect over the carrier with the substrate exposed.

2. The system as claimed in claim 1 further comprising:
mounting an integrated circuit device over the carrier; and
wherein mounting the flip chip over the carrier includes:
mounting the flip chip over the integrated circuit device.

3. The system as claimed in claim 1 further comprising:
mounting a conductive shield over the carrier; and
wherein mounting the flip chip over the carrier includes:
mounting the flip chip over the conductive shield.

4. The system as claimed in claim 1 wherein mounting the flip chip over the carrier includes facing a backside lamination attached to the non-active side to the carrier.

5. The system as claimed in claim 1 wherein mounting the substrate over the flip chip includes connecting the substrate with a conductive bump attached to an active side of the flip chip.

6. An integrated circuit package system comprising:
mounting a flip chip over a carrier with a non-active side of the flip chip facing the carrier;
mounting a substrate over the flip chip with a conductive bump connected between the flip chip and the substrate;
connecting an internal interconnect between the flip chip and the carrier; and
forming an encapsulation over the flip chip, the internal interconnect, and the carrier with an exposed side of the substrate coplanar with a top side of the encapsulation.

7. The system as claimed in claim 6 further comprising:
mounting a further flip chip over the carrier; and
wherein mounting the flip chip over the carrier includes:
mounting the flip chip over the further flip chip.

8. The system as claimed in claim 6 further comprising:
mounting an integrated circuit die over the carrier;
connecting the internal interconnect between the integrated circuit die and the carrier; and
wherein mounting the flip chip over the carrier includes:
mounting the flip chip over the integrated circuit die.

9. The system as claimed in claim 6 further comprising:
mounting a conductive shield having an aperture over the carrier; and
wherein:
mounting the flip chip over the carrier includes:
mounting the flip chip over the conductive shield; and
forming the encapsulation includes:
filling the aperture with the encapsulation.

10. The system as claimed in claim 6 further comprising mounting a device over the substrate.

11. An integrated circuit package system comprising:
a carrier;
a flip chip over the carrier with a non-active side of the flip chip facing the carrier;
a substrate over the flip chip;
an internal interconnect between the flip chip and the carrier; and
an encapsulation over the flip chip, the internal interconnect, and the carrier with the substrate exposed.

12. The system as claimed in claim 11 further comprising:
an integrated circuit device over the carrier; and
wherein the flip chip is over the integrated circuit device.

13. The system as claimed in claim 11 further comprising:
a conductive shield over the carrier; and
wherein the flip chip over the conductive shield.

14. The system as claimed in claim 11 wherein the flip chip over the carrier includes a backside lamination attached to the non-active side facing the carrier.

15. The system as claimed in claim 11 wherein the substrate connected with a conductive bump attached to an active side of the flip chip.

16. The system as claimed in claim 11 wherein:
the substrate connected with a conductive bump attached to an active side of the flip chip;
the encapsulation is coplanar with an exposed side of the substrate.

17. The system as claimed in claim 16 further comprising:
mounting a further flip chip over the carrier; and
wherein mounting the flip chip over the carrier includes:
mounting the flip chip over the further flip chip.

18. The system as claimed in claim 16 further comprising:
an integrated circuit die over the carrier with the internal interconnect between the integrated circuit die and the carrier; and
wherein the flip chip is over the integrated circuit die.

19. The system as claimed in claim 16 further comprising:
a conductive shield having an aperture over the carrier; and
wherein:
the flip chip over is over the conductive shield; and
the encapsulation is in the aperture.

20. The system as claimed in claim 16 further comprising a device over the substrate.
